(19) United States
(12) Patent Application Publication
(10) Pub. No.: US 2013/0130509 A1
(43) Pub. Date: May 23, 2013

(54) COMBINATORIAL SPOT RASTERING FOR FILM UNIFORMITY AND FILM TUNING IN SPUTTERED FILMS

(71) Applicants: Kent Riley Child, Dublin, CA (US); Tony P. Chiang, Campbell, CA (US)

(72) Inventors: Kent Riley Child, Dublin, CA (US); Tony P. Chiang, Campbell, CA (US)

(73) Assignee: Intermolecular, Inc., San Jose, CA (US)

(21) Appl. No.: 13/301,333

(22) Filed: Nov. 21, 2011

(51) Int. Cl. C23C 16/458; H01L 21/02

(52) U.S. Cl. 438/758; 118/729; 257/E21.002

(57) ABSTRACT

A substrate clamped to a stage is moved in a rastering motion in a site-isolated deposition chamber. The raster pattern may be a radial pattern, predetermined X-Y pattern, horizontal/vertical pattern or random (free-form) pattern. The chamber includes a sputter source to generate the sputtered material which is delivered through an aperture positioned over the substrate. By moving the substrate in a rastering motion, the sputtered material is deposited more equally and uniformly.

### TECHNICAL FIELD

The present disclosure relates generally to semiconductor manufacturing and in particular to combinatorial spot rastering for film uniformity and film tuning in sputtered films.

### BACKGROUND

Semiconductor processing or manufacturing techniques are used in the manufacture of integrated circuits (IC) semiconductor devices, flat panel displays, optoelectronics devices, data storage devices, magneto electronic devices, magneto optic devices, packaged devices, and the like. As feature sizes continue to shrink on these devices, improvements, whether in materials, unit processes, or process sequences, are continually being sought for in these semiconductor processes. In order to identify different materials, evaluate different unit process conditions or parameters, or evaluate different sequencing and integration of processes, and combinations thereof, it is desirable to process different regions of the substrate differently. This capability is called “combinatorial processing”, and it is generally not performed with tools that are designed specifically for conventional full substrate processing. It is also desirable to subject localized regions of the substrate to different processing conditions (e.g., localized deposition) in one step of a sequence followed by subjecting the full substrate to a similar processing condition (e.g., full substrate deposition) in another step.

Deposition processes are commonly used in semiconductor manufacturing to deposit a layer of material onto a substrate. Physical vapor deposition (PVD) is one example of a deposition process, and sputtering is a common physical vapor deposition method. In sputtering, target material is ejected from a target material by high-energy particle bombardment and then deposited onto the substrate.

For localized deposition (i.e., deposition on a localized region of the substrate), PVD tools typically include an aperture through which the sputtered material is targeted. Due to the nature of off-angle or vertically-aligned sputtering, the sputtered material does not equally arrive at and through the aperture. This causes the sputtered ions to be unequally or non-uniformly deposited onto the substrate. In addition, the sputtered ions do not leave the target surface at the same angle due to the nature of target erosion. This also causes the sputtered ions to be unequally or non-uniformly deposited onto the substrate.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to one aspect of the invention, semiconductor chamber for combinatorial processing of a substrate is disclosed that includes at least one sputter source configured to deposit sputter ions on the substrate; a movable support configured to support the substrate; and an aperture between the sputter gun and the movable support to isolate a site on the substrate on which the sputter ions are deposited, wherein the movable support is movable in a rastering motion during the deposition of the sputter ions.

The chamber may include a plurality of sputter sources.

The movable support may be an electrostatic chuck.

The rastering motion may be a radial raster pattern, a predetermined X-Y pattern, a horizontal and vertical raster pattern, and/or a random pattern.

According to another aspect of the invention, a method of processing a substrate is disclosed that includes depositing sputtered material on a substrate positioned on a movable support through an aperture that isolates a specific region (or site) on the wafer; and moving the movable support in a rastering motion while depositing the sputter ions on the substrate.

The rastering motion may be a radial raster pattern, a predetermined X-Y pattern, a horizontal and vertical raster pattern, and/or a random pattern.

The sputter ions may be deposited from a first sputter source and further comprising depositing sputter ions from a second sputter source.

The method may further include moving the movable support so that another site of the wafer is isolated; depositing sputter ions on the substrate positioned at the other site; and moving the movable support in the rastering motion while depositing the sputter ions on the substrate at the other site.

According to a further aspect of the invention, a method of combinatorial processing of a substrate is disclosed that includes processing regions on the substrate in a site-isolated manner; and moving the substrate in a rastering motion during the processing.

The rastering motion may be a radial raster pattern, a horizontal and vertical raster pattern, and/or a random pattern.

The processing may include sputtering. Sputter ions may be deposited from at least one sputter source.

The method may also include moving the substrate to a second site; and processing regions on the substrate in a site-isolated manner at the second site; and moving the substrate in a rastering motion during the processing at the second site. The processing at the second site may be sputtering.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 is a simplified schematic diagram illustrating an exemplary sputter processing chamber according to one embodiment of the invention.

FIG. 5 is a schematic diagram illustrating movement of the substrate support to expose multiple regions of a substrate according to one embodiment of the invention.

FIG. 6 is a schematic diagram illustrating a pattern of multiple regions achieved by moving the substrate and/or sputter guns according to one embodiment of the invention.

FIG. 7 is a schematic diagram illustrating the deposition of sputter ions on the substrate through the aperture in further detail according to one embodiment of the invention.

FIG. 8A is a schematic pattern illustrating a radial rastering motion pattern according to one embodiment of the invention.

FIG. 8B is a schematic diagram illustrating a horizontal/vertical and free-form (random) motion pattern according to one embodiment of the invention.

### DETAILED DESCRIPTION

Embodiments of the invention are directed to improved techniques for depositing layers on a substrate to achieve equal and uniform deposition than the prior art techniques. In embodiments of the invention, systems and methods are provided to move a substrate, which is clamped to a stage, in a rastering motion during deposition in a site-isolated deposition chamber. The rastering motion may follow a raster pattern, which may be a radial pattern or in a predefined X-Y pattern and/or random (free-form) pattern.

The manufacture of semiconductor devices entails the integration and sequencing of many unit processing steps. As an example, semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as semiconductor devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, the entireties of which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005, the entireties of which are all herein incorporated by reference.

HPC processing techniques have been successfully adapted to wet chemical processing such as etching, texturing, polishing, cleaning, etc. HPC processing techniques have also been successfully adapted to deposition processes such as sputtering, atomic layer deposition (ALD), and chemical vapor deposition (CVD).

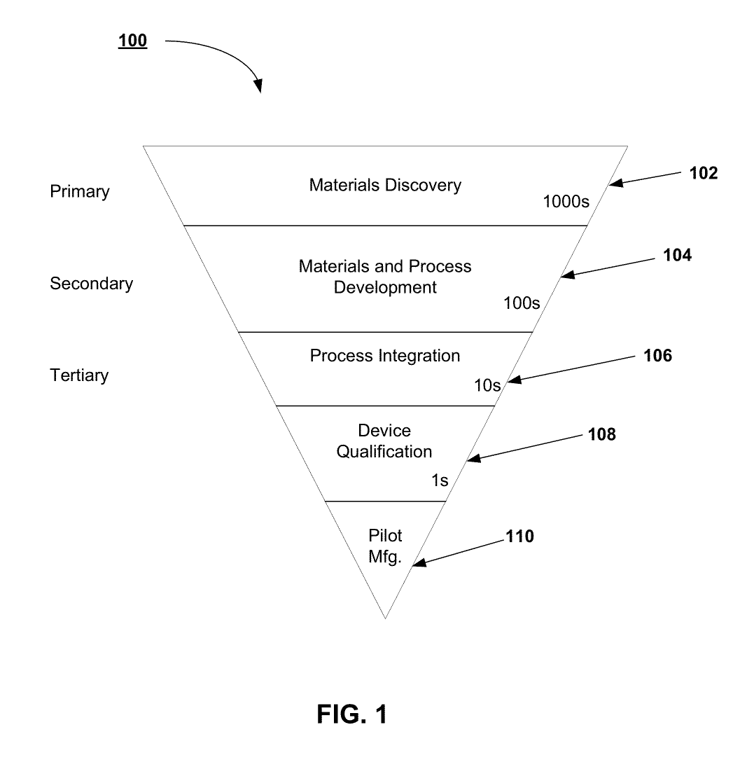

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

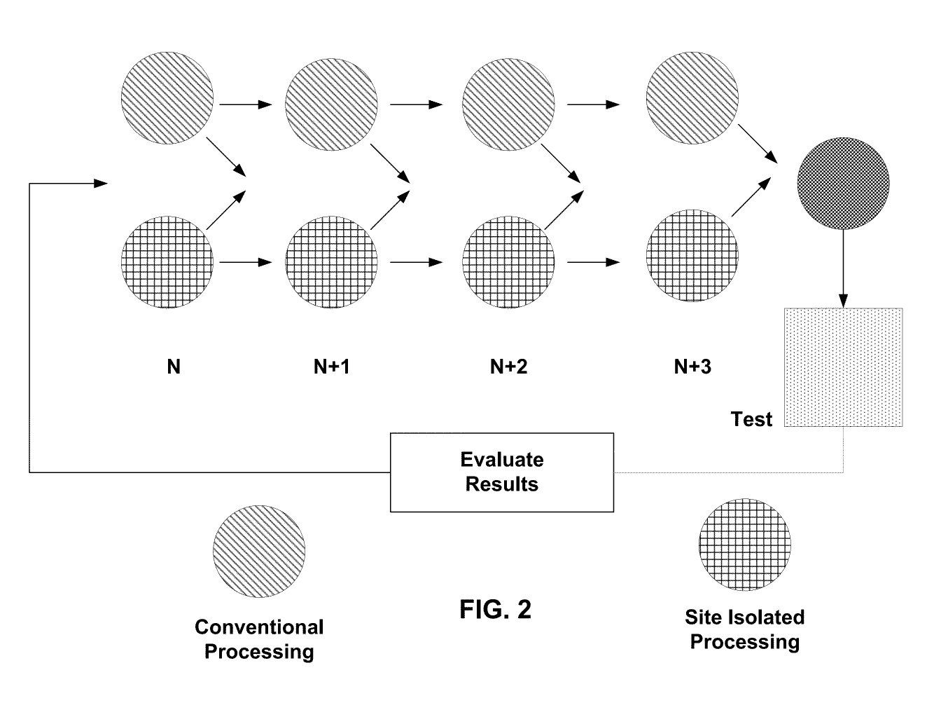

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It will be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It will be appreciated that these process parameters are exemplary and not meant to be an exhaustive list as other process parameters commonly used in semiconductor manufacturing may be varied.

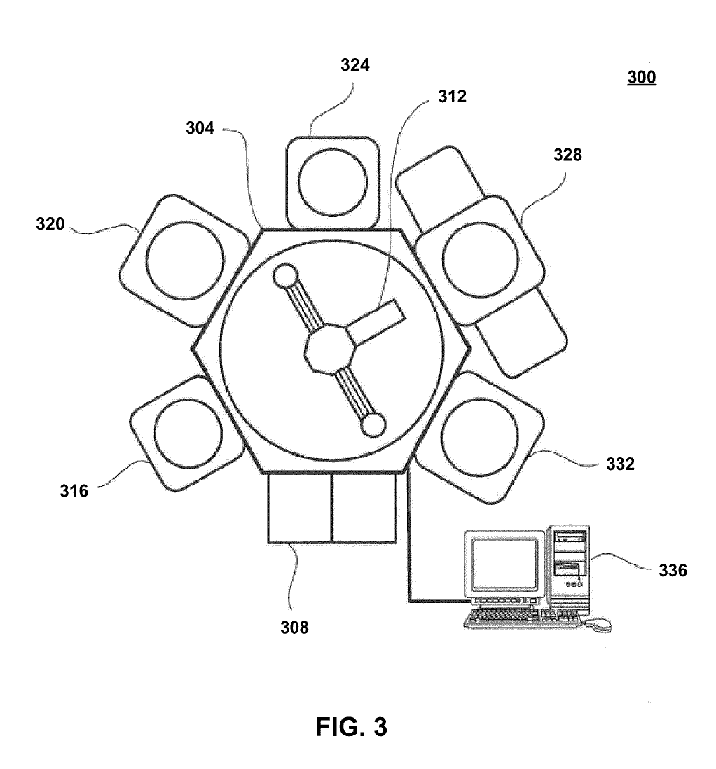

FIG. 3 is a simplified schematic diagram illustrating an integrated high productivity combinatorial (HPC) system 300 in accordance with some embodiments of the invention. HPC system includes a frame 304 supporting a plurality of processing modules. It will be appreciated that frame 304 may be a unitary frame in accordance with some embodiments. In some embodiments, the environment within frame 304 is controlled. Load lock 308 provides access into the plurality of modules of the HPC system. Robot 312 provides for the movement of substrates (and masks) between the modules and for the movement into and out of the load lock 308. Modules 316-332 may be any set of modules and preferably include one or more combinatorial modules. For example, module 316 may be an orientation/degassing module, module 320 may be a clean module, either plasma or non-plasma based, modules 324 and/or 328 may be combinatorial/conventional dual purpose modules. Module 332 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 336, may control the processes of the HPC system. Further details of one possible HPC system are described in U.S. application Ser. Nos. 11/672,478 and 11/672,473. In a HPC system, a plurality of methods may be employed to deposit material upon a substrate employing combinatorial processes.

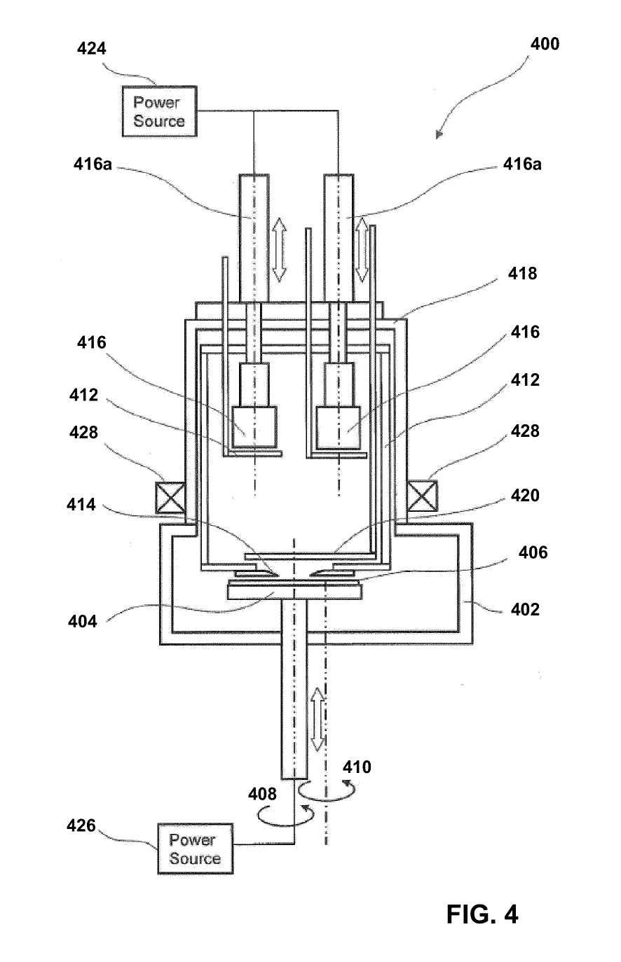

FIG. 4 is a simplified schematic diagram illustrating an exemplary sputter chamber 400 configured to perform combinatorial processing and full substrate processing in accordance with some embodiments of the invention. It will be appreciated that the processing chamber shown in FIG. 4 is merely exemplary and that other deposition chambers may be used with the invention. Further details on exemplary deposition chambers that can be used with the invention can be found in U.S. Pat. No. 8,039,052, entitled “Multi-Region Processing System and Heads”, filed on Dec. 27, 2007 and claiming priority to U.S. Provisional Application No. 60/970,500 filed on Sep. 6, 2007, and U.S. patent application Ser. No. 12/027,980, entitled “Combinatorial Process System”, filed Feb. 7, 2008, and claiming priority to U.S. Provisional Application No. 60/969,955 filed on Sep. 5, 2007, the entireties of which are hereby incorporated by reference.

The processing chamber 400 includes a bottom chamber portion 402 disposed under a top chamber portion 418. A substrate support 404 is provided within the bottom chamber portion 402. The substrate support 404 is configured to hold a substrate 406 disposed thereon and can be any known substrate support, including but not limited to a vacuum chuck, electrostatic chuck or other known mechanisms.

Substrate 406 may be a conventional round 200 mm, 300 mm, or any other larger or smaller size. In other embodiments, substrate 406 may be a square, rectangular, or other shaped substrate. The substrate 406 may be a blanket substrate, a coupon (e.g., partial wafer), or even a patterned substrate having predefined regions. In some embodiments, substrate 406 may have regions defined through site-isolated processing as described herein.

The top chamber portion 418 of the chamber 400 includes a process kit shield 412, which defines a confinement region over a portion of the substrate 406. As shown in FIG. 4, the process kit shield 412 includes a sleeve having a base (optionally integrated with the shield) and an optional top. It will be appreciated, however, that the process kit shield 412 may have other configurations. The process kit shield 412 is configured to confine a plasma generated in the chamber 400 by process guns 416. The generated plasma dislodges ions from a target and the sputtered ions are deposited on an exposed surface of substrate 406. In some embodiments, the process kit shield 412 may be moved in and out of chamber 400, and, in other embodiments, the process kit shield 412 remains in the chamber for both full substrate and combinatorial processing.

The base of process kit shield 412 includes an aperture 414 through which a surface of substrate 406 is exposed for deposition processing. The chamber may also include an aperture shutter 420 which is moveably disposed over the base of process kit shield 412. The aperture shutter 420 slides across a bottom surface of the base of process kit shield 412 in order to cover or expose aperture 414. In some embodiments, the aperture shutter 420 is controlled by an arm extension (not shown) which moves the aperture shutter to expose or cover aperture 414.

As shown in FIG. 4, the chamber 400 includes two process guns 416. While two process guns are illustrated, any number of process guns may be included, e.g., one, three, four or more process guns may be included. Where more than one process gun is included, the plurality of process guns may be referred to as a cluster of process guns.

The process guns 416 are moveable in a vertical direction so that one or both of the guns may be lifted from the slots of the shield. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc. and the tilt angle may be varied.

The chamber may also include a gun shutter 422, which seals off the deposition gun when the process gun 416 is not needed during processing. The gun shutter 422 allows one or more of the process guns 416 to be isolated from certain processes as needed. It will be appreciated that slide cover plate 422 may be integrated with the top of the process kit shield 412 to cover the opening as the process gun 416 is lifted or individual cover plate 422 can be used for each process gun 416.

The process guns 416 may be fixed to arm extensions 416a to vertically move process guns 416 toward or away from a top plate of top chamber portion 418. The arm extensions 416a may be attached to a drive, e.g., lead screw, worm gear, etc. The arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It will be appreciated that process guns 416 may alternatively tilt away from aperture 414.

The chamber also includes power sources 424 and 426. Power source 424 provides power for sputter guns 416, and power source 426 provides RF bias power to the substrate support 404. In some embodiments, the output of the power source 426 is synchronized with the output of power source 424.

The chamber 400 may also include a magnet 428 disposed around an external periphery of the chamber 400. The magnet 428 is located between the bottom surface of sputter guns 416 and a top surface of substrate 406. The magnet 428 improves ion guidance as the magnetic field distribution above substrate 406 is re-distributed or optimized to guide metal ions on to the substrate. The magnet 428 may be a permanent magnet or an electromagnet.

The substrate support 404 is capable of both rotating around its own central axis 408 (referred to as “rotation” axis), and rotating around an exterior axis 410 (referred to as “revolution” axis). Such dual rotary substrate supports can be advantageous for combinatorial processing using site-isolated mechanisms. Other substrate supports, such as an XY table, can also be used for site-isolated deposition. In addition, substrate support 404 may move in a vertical direction. It will be appreciated that the rotation and movement in the vertical direction may be achieved through one or more known drive mechanisms, including, for example, magnetic drives, linear drives, worm screws, lead screws, differentially pumped rotary feeds, and the like.

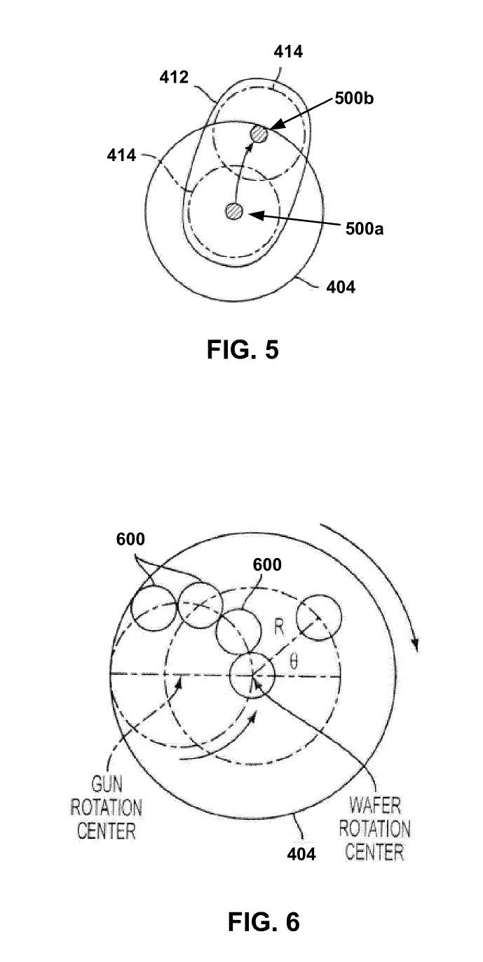

Through the rotational movement of the process kit shield 412 and the corresponding aperture 414 in the base of the process kit shield, in combination with the rotational movement of substrate support 404, any region of a substrate 406 may be accessed for combinatorial processing. For example, FIG. 5 illustrates movement of the process kit shield 412 and the corresponding aperture 414 combined with rotational movement of the substrate support 404 to change the deposition site from a first region 500a on the substrate 406 to a second region 500b on the substrate 406.

The dual rotary substrate support 404 allows any region (i.e., location or site) of the substrate 406 to be placed under the aperture 414; hence, site-isolated deposition is possible at any location on the substrate 406. For example, FIG. 6 illustrates a pattern achieved by moving the substrate 406, the process kit shield 412, and/or the process gun(s) 416 as described above. As the process kit shield 412 and the process gun(s) 416 rotate, radial movement across the substrate surface is provided in order to define a number of regions 600. Rotation of the substrate 406 enables access to substantially the entire substrate 406 and allows processing or deposition over multiple regions 600 of the substrate 406. The regions 600 may overlap and/or the regions can be isolated.

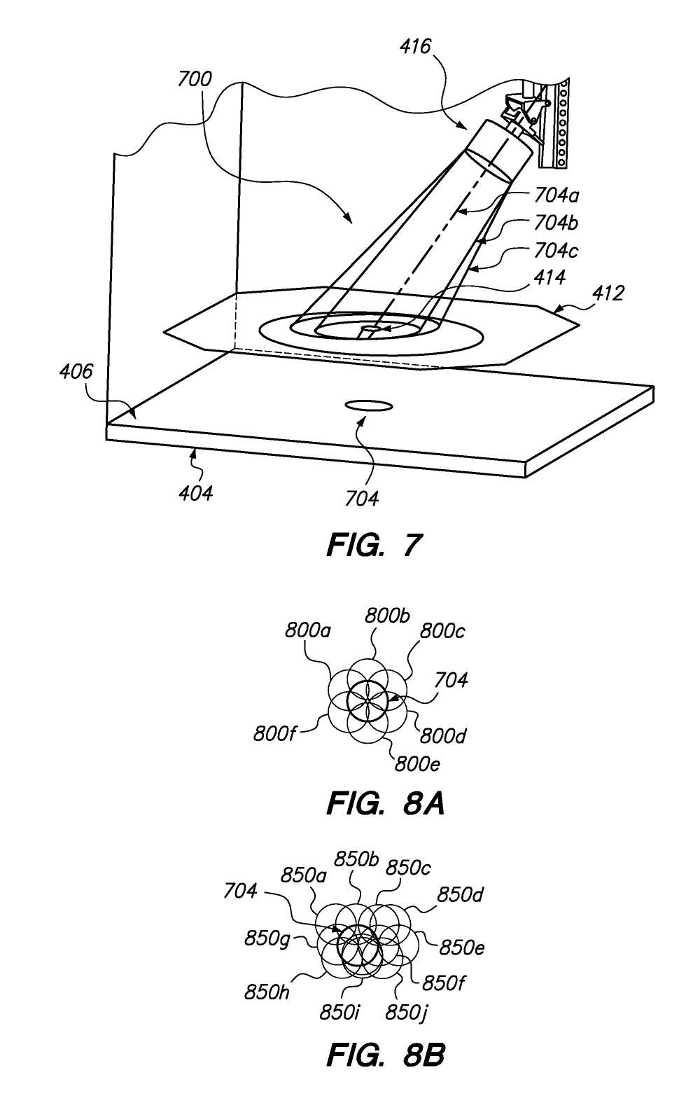

FIG. 7 is a detailed schematic view illustrating site isolated deposition of sputter ions 700 on the substrate 406 in accordance with embodiments of the invention. As shown in FIG. 7, a process gun 416 is angled at the aperture 414 so that sputter ions 700 are directed on a region 704 of the substrate 406. As described above, a process kit shield 412 having an aperture 414 is provided through which the sputter ions are directed to deposit a layer on the substrate 406 at region 704.

As described above, due to the nature of off-angle or vertically-aligned sputtering and/or the target erosion, the sputtered ions 700 do not equally arrive at and through the aperture 414. For example, as shown in FIG. 7, sputter ions 704a arrive before sputter ions 704b, which, in turn, arrive before sputter ions 704c. This causes the sputtered ions to be unequally or non-uniformly deposited onto the substrate 406 using conventional deposition techniques.

In accordance with embodiments of the invention, to achieve uniform deposition of the sputter ions 704 on the substrate 406, the substrate 406 is moved in a rastering motion during deposition by moving the substrate support 404 in a rastering motion. The rastering motion may follow a raster pattern, which may be a radial raster pattern, a predefined X-Y raster pattern, and/or a random pattern. FIG. 8A illustrates an exemplary radial raster pattern, and FIG. 8B illustrates an exemplary horizontal and vertical raster pattern or an exemplary random pattern.

In a particular example, as shown in FIG. 8A, the substrate support 404 is rotated so that site 800a, site 800b, site 800c, site 800d, site 800e and site 800f are targeted during deposition. Although six sites are shown in FIG. 8A, it will be appreciated that the raster pattern may include more less than or more than six sites (e.g., any value or range of values between about three and hundreds of sites). The substrate support may remain at each site 800 for any desired or suitable time duration. Because the aperture 414 is not moved during the radial raster movement of the substrate support 404 during the deposition, a layer is only deposited on the region 704 of the substrate 406. The deposited layer is substantially uniform and equal at region 704 as a result of the movement of the substrate 706 in the radial raster pattern.

As shown in FIG. 8B, the substrate support is moved so that sites 812a-j are targeted during deposition. In the X-Y raster pattern example, the sites 850a-j are targeted in order (e.g., site 850a, followed by site 850b, site 850c and then site 850d in a X-horizontal motion, then site 850e in a Y-horizontal motion, and then site 850f in another horizontal motion and so on.). In the random or free-form raster pattern example, the sites 850a-j are not necessarily targeted in order, and the motion may be a combination of radial and horizontal/vertical motions (e.g., site 850a, followed by site 850i, then site 850d, etc.). Although ten sites 850 are shown in FIG. 8B, it will be appreciated that the raster pattern may include more less than or more than ten sites (e.g., any value or range of values between about three and hundreds of sites). The substrate support may remain at each site 850 for any suitable or desired time duration. Because the aperture 414 is not moved during the horizontal/vertical and/or random raster movement of the substrate support 404 during the deposition, a layer is only deposited on the region 704 of the substrate 406. The deposited layer is substantially uniform and equal at region 704 as a result of the movement of the substrate 706 in the horizontal and vertical or random raster pattern.

The raster pattern may be programmed into a controller, such as controller 336 or a drive controller coupled to the substrate support drive mechanism, in order to achieve the desired deposition characteristics. The raster pattern may be embodied in a computer-readable medium on which is stored one or more sets of instructions (e.g., software). The software may reside, completely or at least partially, within memory and/or within a processor of the controller during execution thereof. The term “computer-readable medium” should be taken to include a single medium or multiple media that store the one or more sets of instructions. The term “computer-readable medium” shall also be taken to include any medium that is capable of storing, encoding or carrying a set of instructions for execution by a machine and that cause a machine to perform any one or more of the methodologies of the present invention. The term “computer-readable medium” shall accordingly be taken to include, but not be limited to, solid-state memories, and optical and magnetic media.

The invention has been described in relation to particular examples, which are intended in all respects to be illustrative rather than restrictive. Various aspects and/or components of the described embodiments may be used singly or in any combination. It is intended that the specification and examples be considered as exemplary only, with a true scope and spirit of the invention being indicated by the claims.

What is claimed is:

1. A semiconductor chamber for combinatorial processing of a substrate comprising:
at least one sputter source configured to deposit sputtered material on a substrate;
a movable support configured to support the substrate; and
an aperture between the sputter source and the movable support operable to isolate a site of the substrate on which the sputtered material is deposited,
wherein the movable support is movable in a rastering motion during the deposition of the sputtered material.

2. The semiconductor chamber of claim 1, wherein the chamber comprises a plurality of sputter sources.

3. The semiconductor chamber of claim 1, wherein the movable support is an electrostatic chuck.

4. The semiconductor chamber of claim 1, wherein the rastering motion comprises movement in a radial raster pattern.

5. The semiconductor chamber of claim 1, wherein the rastering portion comprises a raster pattern.

6. The semiconductor chamber of claim 1, wherein the rastering motion comprises a random pattern.

7. A method of processing a substrate comprising:
depositing sputtered material on the substrate positioned on a movable support through an aperture that isolates a site on the substrate;
moving the movable support in a rastering motion while depositing the sputtered material on the substrate.

8. The method of claim 7, wherein the rastering motion comprises a radial raster portion.

9. The method of claim 7, wherein the rastering motion comprises a predetermined X-Y raster pattern.

10. The method of claim 7, wherein the sputtered material is deposited from a first sputter source and further comprising depositing sputtered material from a second sputter source.

11. The method of claim 7, wherein the rastering motion comprises a random pattern.

12. The method of claim 7, further comprising:
moving the substrate support so that another site isolated region of the substrate is under the aperture;
depositing sputtered material on the substrate positioned at the other site; and
moving the movable support in the rastering motion while depositing the sputtered material on the substrate at the other site.

13. A method of combinatorial processing of a substrate comprising:
processing regions on the substrate by physical vapor deposition in a site-isolated manner; and
moving the substrate in a rastering motion during the processing.

14. The method of claim 13, wherein the rastering motion comprises a radial raster portion.

15. The method of claim 13, wherein the rastering motion comprises a predetermined X-Y raster pattern.

16. The method of claim 13, wherein the rastering motion comprises a random pattern.

17. The method of claim 13, wherein the processing by physical vapor deposition comprises sputtering.

18. The method of claim 17, wherein sputtered material is deposited from at least one sputter source.

19. The method of claim 13, further comprising:
moving the substrate to a second site; and
processing regions on the substrate in a site-isolated manner at the second site; and
moving the substrate in a rastering motion during the processing at the second site.

20. The method of claim 19, wherein the processing at the second site comprises sputtering.
